(19) United States
(12) Patent Application Publication
(10) Pub. No.: US 2017/0025165 A1
(43) Pub. Date: Jan. 26, 2017

(54) METHOD, SYSTEM, AND APPARATUS FOR MEMORY WITH FEEDTHROUGH AND RETIMING PATHS TO SUPPORT MEMORY TO MEMORY REQUESTS

(71) Applicant: Broadcom Corporation, Irvine, CA (US)

(72) Inventors: Mark Fairhurst, Stockport (GB); Travis R. Hebig, Lakeville, MN (US)

(21) Appl. No.: 14/815,270

(22) Filed: Jul. 31, 2015

Related U.S. Application Data
(60) Provisional application No. 62/195,587, filed on Jul. 22, 2015.

(51) Int. Cl. G11C 11/419

(52) U.S. Cl. CPC G11C 11/419

(57) ABSTRACT

Memory systems, such as SRAM systems, are described that comprise a series of adjacently placed memory components for providing memory data and memory transaction information from one component to another. Input pins are strategically placed, and muxing and ancillary logic are included within memory components, to allow for the adjacent placement. The memory data and memory transaction information are provided by a memory component in a configurable feedthrough or pipelined manner based on the period of an operating clock. The memory data and memory transaction information are received by a memory system at only a first memory component in the series, and are provided from the memory system by only a last memory component in the series. Memory components selectively provide to subsequent memory components in the series either locally stored data, or data received by the memory components as an input.

### CROSS-REFERENCE TO RELATED APPLICATIONS

This application claims the benefit of U.S. Provisional Application No. 62/195,587, filed on Jul. 22, 2015, the entirety of which is incorporated by reference herein.

### BACKGROUND

I. Technical Field

Embodiments described herein relate to semiconductor-based memory devices and systems.

II. Background Art

Devices, e.g., personal computers and servers, cellular and smart phones, PDAs, gaming consoles, home electronics and entertainment devices, etc., include memory(ies) such as random access memory (RAM) and static RAM (SRAM) for data storage. Prior solutions for SRAMs involve building a memory or memory system from individual instances or blocks of existing SRAM architectures, e.g., from memory block libraries. For example, one or more blocks of an existing 0.5 Mb to 2 Mb SRAM (e.g., up to 64 blocks or more) may be connected together to effectively create a larger memory system such as a 16k×1680 payload memory.

Yet, building a high-capacity, high-performance memory system using instances of SRAM blocks based on current memory architectures as building blocks is area inefficient. For instance, FIG. 1 shows a prior art SRAM system 100 that uses ‘L’ existing pre-compiled SRAM blocks 102 (e.g., where ‘L’ may be up to a value of 64). Such a memory system may be efficient from a design or manufacturing perspective, however the area around the ‘L’ pre-compiled SRAM blocks 102 contains a corresponding ‘L’ instances of ancillary logic 104 which may include memory select logic, buffering, register stages, etc., as well as routing channels such as a control/data input 108 and a block data output 110 (which may each include a plurality of traces). These areas are lightly used/populated which impacts the area efficiency of the total memory footprint, and signal traces between pre-compiled SRAM blocks 102 increases signal routing difficulty. While not shown for illustrative clarity, each trace of block data output 110 from a given pre-compiled SRAM block 102 may also pass through additional ancillary logic blocks and muxing to further increase area inefficiency and routing difficulty. In some systems, hundreds of data lines (‘M’) from the instances of pre-compiled SRAM blocks 102 must be muxed together at the output of SRAM system 100 using an ‘L:1’ mux 106 to output a single system data line 112. Mux 106 may be distributed, e.g., 4:1 muxes every for every three memory blocks, but this configuration still has active region and routing channel penalties.

Additionally, timing closure of a large memory system using large numbers of instances of SRAMs as building blocks is increasingly difficult due to system scale. The increasing size of internal memory arrays creates timing issues for routing signals in parallel both to and from each of the SRAM instances.

### BRIEF SUMMARY

Methods, systems, and apparatuses are described for memories with feedthrough and retiming paths to support memory to memory requests, substantially as shown in and/or described herein in connection with at least one of the figures, as set forth more completely in the claims.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1 shows a block diagram of a prior art SRAM system that uses pre-compiled SRAM blocks.

FIG. 2 shows a block diagram of a memory system, according to an example embodiment.

FIG. 3 shows a block diagram of a memory system, according to an example embodiment.

FIG. 4 shows a block diagram of a memory component of a memory system, according to an example embodiment.

FIG. 5 shows a flowchart for performing feedthrough operations and retiming on data and information paths to support memory to memory requests, according to an example embodiment.

FIG. 6 shows a flowchart for performing feedthrough operations and retiming on data and information paths to support memory to memory requests, according to an example embodiment.

FIG. 7 shows a flowchart for performing feedthrough operations and retiming on data and information paths to support memory to memory requests, according to an example embodiment.

FIG. 8 shows a timing diagram for performing feedthrough operations and retiming on data and information paths to support memory to memory requests, according to an example embodiment.

FIG. 9 shows a block diagram of a computing device/system in which the techniques disclosed herein may be performed and the embodiments herein may be utilized.

Embodiments will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### I. Introduction

The present specification discloses numerous example embodiments. The scope of the present patent application is not limited to the disclosed embodiments, but also encompasses combinations of the disclosed embodiments, as well as modifications to the disclosed embodiments.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In the discussion, unless otherwise stated, adjectives such as “substantially” and “about” modifying a condition or relationship characteristic of a feature or features of an embodiment of the disclosure, are understood to mean that the condition or characteristic is defined to be within tolerances that are acceptable for operation of the embodiment for an application for which it is intended.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

Still further, it should be noted that the drawings/figures are not drawn to scale unless otherwise noted herein.

Numerous exemplary embodiments are now described. Any section/subsection headings provided herein are not intended to be limiting. Embodiments are described throughout this document, and any type of embodiment may be included under any section/subsection. Furthermore, it is contemplated that the disclosed embodiments may be combined with each other in any manner. That is, the embodiments described herein are not mutually exclusive of each other and may be practiced and/or implemented alone, or in any combination.

### II. Example Embodiments

The example techniques and embodiments described herein may be adapted to various types of systems and devices, such as but without limitation, communication devices (e.g., cellular and smart phones, etc.), communication systems and components (e.g., switches, routers, etc.), computers/computing devices, computing systems, electronic devices, gaming consoles, home electronics and entertainment devices, and/or the like, that use memory such as SRAM. While the embodiments herein may be described with respect to SRAM as conceptual and/or illustrative examples for descriptive consistency, other types of memory implementations are also contemplated by implementing the disclosed techniques.

The techniques described herein provide novel SRAM component instances (“blocks”) that contain muxes, ancillary logic, and pins placed so that contiguous instances of the SRAM components may be tiled together adjacently (e.g., no physical, external connections or logic therebetween) to form a memory system, thus minimizing any unused space around the memories and simplifying routing. The SRAM component instances may be configured with bypass select inputs to provide either a signal retiming function or a feedthrough function (i.e., data is pipelined in a retiming memory component or flows through a feedthrough memory component). In embodiments, stages of latency may be minimized by configuring more feedthrough memory components, and the operating system clock frequency may be maximized by configuring more retiming (i.e., pipeline) memory components.

The SRAM component instances may be organized into groups of ‘P’ feedthrough memory components per one retiming memory component. This ratio (‘P:1’) and the number of these groups may be configured based on the memory system requirements. For instance, a memory system operating with a relatively short clock period or cycle length, i.e., a higher clock frequency, may have fewer feedthrough memory components per retiming memory component (a lower ratio ‘P:1’) than a memory system having a relatively long clock period or cycle length, i.e., a slower clock frequency. As described herein, a bypass selector configuration input for memory component instances may be applied to configure individual memory components as being feedthrough or retimed (pipelined).

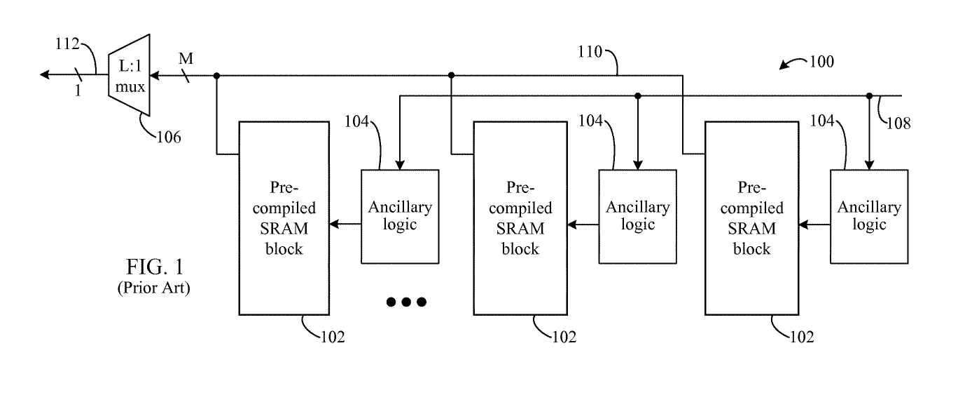

In embodiments, memory components included in a memory system may comprise one or more series of memory components, such as is described below with respect to FIG. 1. Example memory systems according to the described techniques may only apply inputs to the first memory component of a series of memory components in the memory systems, and data passes through the memory systems from memory component to memory component (e.g., from previous memory components of a series to subsequent memory components of the series). Each memory component may be configured to determine if it is the intended recipient for memory transactions or operations, e.g., as indicated by memory component identifiers included in memory transaction/operation information. If a memory component determines that it is the intended recipient, that memory component performs the operation; if not, that memory component passes all of the memory system inputs (i.e., memory transaction information and data) along to the next memory component in the memory system. All memory system information and/or data paths may be conveyed from memory component to memory component in embodiments. According to embodiments, the last memory component of a series of memory components in memory systems may be the only memory component to provide its outputs to a receiver that is external to the memory system.

According to one or more embodiments described herein, all logic, including but not limited to muxes and ancillary logic, to support the memory component to memory component paths may be included within the memory component instances themselves. This allows for little or no logic and routing channels needed between the memory components for area savings. Accordingly, key timing paths, e.g., for memory data and memory transaction information, may also be configured as memory component to memory component dependent with little or no external buffering or spacing and no external registers to greatly simplify system level timing and allow for maximum system operating frequencies to be utilized. Input pins of signals for data and information that correspond to individual instances of memory components may be placed such that adjacent placement of memory components in a memory system is possible (e.g., pins at non-adjacent edges, pins connected to signal traces underneath memory components using vias, etc.).

As noted, ancillary logic (e.g., memory select logic, feedthrough buffering, register stages, etc.) and muxes required by the memory components are included within each of the memory components. In embodiments, a memory system described herein also includes a local selector, e.g., a mux or a 2:1 mux, that is configured to selectively output either: 1) read data stored in a given memory component for a valid read operation targeting the memory component, or 2) input read data that is received by the given memory component from either a previous memory component or a source external to the memory system for feedthrough by the memory component. By including a local selector such as 2:1 mux for selecting between local data to be read and received read data, large ‘L:1’ muxes, such as mux 106 shown FIG. 1, may be eliminated.

It is contemplated herein that in various embodiments and with respect to the illustrated figures of this disclosure, one or more components described and/or shown may not be included and that additional components may be included.

The techniques and embodiments described herein provide for improvements in memory systems as described above, including but not limited to SRAM memory systems.

For instance, methods, systems, devices, and apparatuses are provided for improved memory systems. A memory system in accordance with an example aspect is described. The memory system includes a first memory component that includes within, a first selection component, and a second memory component that includes within, a second selection component. The first memory component is configured to receive memory transaction information that is input to the memory system, as well as memory data, and provide to the second memory component the memory transaction information and, based on the first selection component, first memory data stored in the first memory component. The second memory component is configured to receive the memory transaction information and the first memory data from the first memory component, and provide the memory transaction information, as well as provide the first memory data or second memory data stored in the second memory component as an output of the second memory component based on the second selection component.

A memory system in accordance with another example aspect is also described. The memory system includes a first memory component that includes within, a first retiming register, and a second memory component that includes within, a second retiming register. The first memory component is configured to receive memory transaction information input to the memory system, and selectively provide to the second memory component the memory transaction information as a first buffered output, or as a first registered output from the first retiming register. The second memory component is configured to receive the memory transaction information from the first memory component, and selectively provide the memory transaction information as a second buffered output, or as a second registered output from the second retiming register.

A method performed in a memory system in accordance with yet another example aspect is described. The method includes receiving memory transaction information input to the memory system at a first memory component of the memory system, and selectively providing the memory transaction information from the first memory component to a second memory component of the system as a first buffered output or as a first registered output. The method also includes receiving the memory transaction information at the second memory component from the first memory component, and selectively providing the memory transaction information from the second memory component as a second buffered output or as a second registered output.

Various example embodiments are described in the following subsections. In particular, example memory system and memory component embodiments are described. This description is followed by example operational embodiments. Next, further example embodiments and advantages are described, and subsequently an example computer implementation is described. Finally, some concluding remarks are provided. It is noted that the division of the following description generally into subsections is provided for ease of illustration, and it is to be understood that any type of embodiment may be described in any subsection.

### III. Example Memory System and Memory Component Embodiments

As noted above, memory systems and components, such as SRAM systems and SRAM blocks/components, may be configured in various ways to improve memory system layouts, routing, and timing. Techniques and embodiments are provided for implementation in and with devices and systems that utilize memories such as SRAMs. For instance, in embodiments, an SRAM system comprised of SRAM components according to the described techniques and embodiments may be implemented in devices and systems such as those enumerated herein.

In embodiments, by way of illustrative example and not limitation, a memory system comprises a plurality of memory components that communicate data and transaction information from memory component to memory component. A memory system may comprise two or more (e.g., up to ‘N’) memory components. These memory components are located adjacent to each other in a memory system, in embodiments, such that little or no logic or communication/data connections are included therebetween. For example, according the described techniques, ancillary logic (e.g., memory select logic, feedthrough buffering, register stages, etc.) and muxing required by the memory components are included within each of the memory components. Furthermore, the memory components are configured such that communication/data connections are passed from one memory component to the next, adjacent memory component. However, it should be noted that embodiments are contemplated herein which utilize various described techniques, such as but not limited to, memory component to memory component paths, feedthrough configurations, and/or retiming configurations, that allow for some logic and/or routing between memory components of a memory system and/or one or more series of adjacent memory components.

Systems and devices, such as memory systems and components, as well as SRAM systems and components, may be configured in various ways with feedthrough and retiming paths to support memory to memory requests according to the techniques and embodiments described herein.

A. Memory System Embodiments

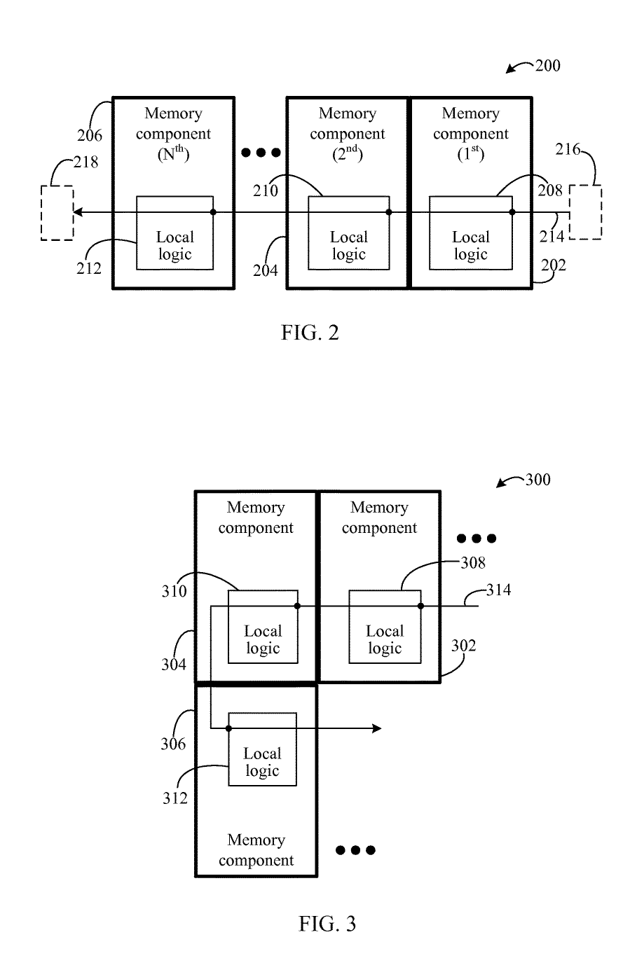

FIG. 2 shows a block diagram of an example memory system 200 for implementing the above-referenced improvements. Memory system 200 may include a plurality of instances of memory components (i.e., memory blocks): a memory component 202, a memory component 204, and a memory component 206 (the ‘Nth’ memory component). Memory component 202 may include within local logic 208, memory component 204 may include within local logic 210, and memory component 206 may include within local logic 212. A memory data and transaction information connector 214 may traverse a portion of, or the entirety of, memory system 200 in a memory component to memory component fashion as shown in FIG. 2, and as described in further detail herein.

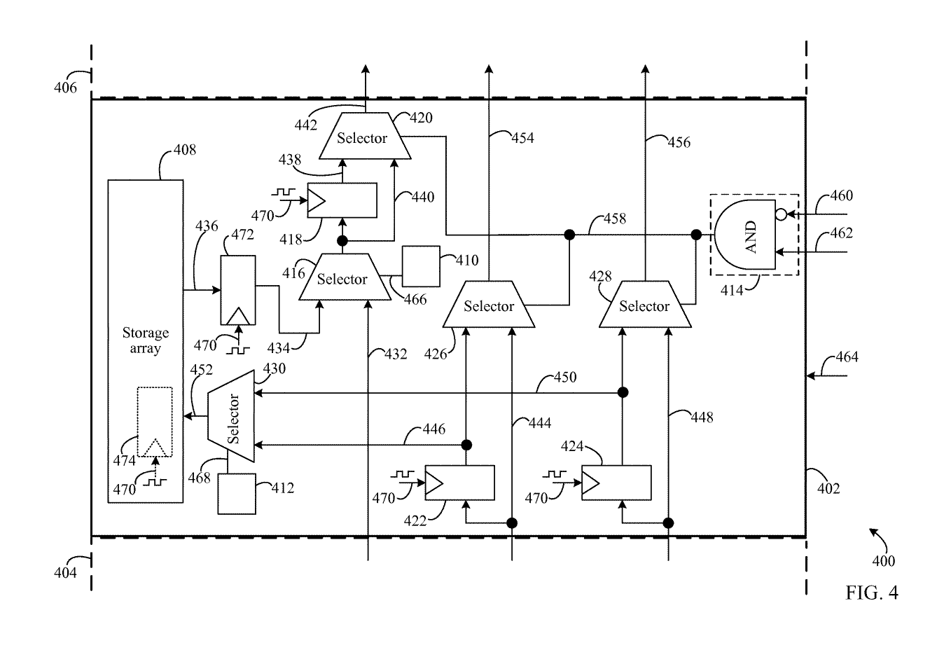

Memory component 202, memory component 204, and memory component 206 are memory blocks that comprise memory system 200. Each memory component may include a storage array (shown in FIG. 4 and described in further detail in the following subsection) configured to store data written to a given memory component and available to be read from a given memory component. Memory system 200 may comprise two or more memory components. In some embodiments, memory component 206 may be excluded from memory system 200 (where memory component 204 would be the final memory component of memory system 200), while in some other embodiments, memory component 206 may be the ‘Nth’ memory component of memory system 200 where N is an integer greater than or equal to 3. Memory component 202, memory component 204, and memory component 206 may be configured to store the same number of memory bits, but the embodiments herein are not so limited. That is, while in embodiments, memory component 202, memory component 204, and memory component 206 may be of the same configuration (i.e., identical or approximately identical memory components), one or more memory components of differing configuration(s) are also contemplated in variations of memory system 200. In embodiments, one or more of memory component 202, memory component 204, and memory component 206 are adjacent to any previous or subsequent memory components on respective edges of these memory components.

Local logic 208, local logic 210, and local logic 212 are each local to (i.e., contained within) memory component 202, memory component 204, and memory component 206, respectively. As noted herein, each local logic component may include ancillary logic associated with its respective memory component, as well as muxes, additional logic, circuits, connections, etc., that are typical to memory components for standard operations. Further details for muxes, ancillary logic, local logic 208, local logic 210, and local logic 212 are described in the following subsection below. Local logic 208, local logic 210, and local logic 212 are each configured to receive memory data and memory transaction information via memory data and transaction information connector 214 from a memory component previous to their respective memory components. Local logic 208 is also configured to receive memory data and memory transaction information via memory data and transaction information connector 214 from a source 216 external to memory system 200 when memory component 202 is the first memory component of memory system 200. Local logic 208, local logic 210, and local logic 212 are each configured to provide memory data and memory transaction information via memory data and transaction information connector 214 to a memory component subsequent to their respective memory components. Local logic 212 is also configured to provide memory data and memory transaction information via memory data and transaction information connector 214 to a receiver 218 external to memory system 200 when memory component 206 is the last memory component of memory system 200. In embodiments, source 216 and receiver 218 may be separate components, may be the same component, or may reside in a single component and be two respective portions thereof

Local logic 208, local logic 210, and local logic 212 are each configured to register (i.e., retime/pipeline) or buffer (i.e., feedthrough via bypass) memory data and memory transaction information traversing their respective memory components based on a bypass indicator or bypass selector configuration input, in embodiments, as described below. Local logic 208, local logic 210, and local logic 212 are also each configured to provide data stored in their respective memory components to a subsequent memory component based on a valid memory read transaction, according to embodiments. Local logic 208, local logic 210, and local logic 212 are each further configured to provide memory data stored in a previous memory component and received therefrom to a subsequent memory component.

In the example embodiment shown in FIG. 2, memory component 202 is the first memory component of memory system 200, and memory component 206 is the last or final memory component of memory system 200. In such an example embodiment, memory component 202 receives signals, such as memory data and memory transaction information, via memory data and transaction information connector 214 from a source component of an external device, e.g., source 216, seeking to read from or write to memory system 200. That is, signals received via memory data and transaction information connector 214 at the first memory component of memory system 200 are from a device such as source 216 that is external to memory system 200. Furthermore, in accordance with the techniques described herein, the first memory component of memory system 200 (e.g., memory component 202 as shown in FIG. 2) may be the only memory component of memory system 200 that receives memory data and memory transaction information via memory data and transaction information connector 214 from a device such as source 216 that is external to memory system 200, e.g., in a single clock cycle. Likewise, as shown in the example embodiment of FIG. 2, memory component 206 is the last memory component of memory system 200 and provides signals, such as memory data and memory transaction information, via memory data and transaction information connector 214 to a receiver component of a device, e.g., receiver 218, that receives data read from or indications related to data written to memory system 200. For some embodiments in accordance with the techniques described herein, the last memory component of memory system 200 (e.g., memory component 206 as shown in FIG. 2) may be the only memory component of memory system 200 that provides memory data and memory transaction information via memory data and transaction information connector 214 to a device such as receiver 218 that is external to memory system 200. In other words, in embodiments, memory data and memory transaction information is input to memory system 200 at only the first memory component, and is output from memory system 200 at only the last memory component—all other intervening memory components receive memory data and memory transaction information from, and provide it to, any other adjacent memory components of memory system 200 in a memory component to memory component fashion.

In embodiments, memory data may comprise read data and/or write data, and memory transaction information may comprise read transaction information, write transaction information, and/or write data. It is contemplated herein that multiple memory transactions may be performed in a single clock cycles by including multiple instance of transaction information connector 214 in memory system 200.

Turning now to FIG. 3, a block diagram of an example memory system 300 is shown. Memory system 300 may be an alternate embodiment of memory system 200 of FIG. 2 with an alternative arrangement of memory components. Memory system 300 may include a plurality of instances of memory components (i.e., memory blocks): a memory component 302, a memory component 304, and a memory component 306. Memory component 302 may include within local logic 308, memory component 304 may include within local logic 310, and memory component 306 may include within local logic 312. A memory data and transaction information connector 314 may traverse a portion of, or the entirety of, memory system 300 in a memory component to memory component fashion as shown in FIG. 3.

Memory component 302, memory component 304, and memory component 306 may be similarly configured as the memory components of memory system 200 of FIG. 2. Local logic 308, local logic 310, and local logic 312, may be similarly configured as the local logic components of memory system 200 of FIG. 2. Memory data and transaction information connector 314 may be similarly configured as memory data and transaction information connector 214 of memory system 200 of FIG. 2. However, as shown in FIG. 3, the arrangement of memory component 302, memory component 304, and memory component 306 with respect to each other differs from the memory components of memory system 200 shown in FIG. 2. For instance, as shown in FIG. 3, memory component 302 is not the first memory component and memory component 306 is not the last memory component of memory system 300. Additionally, the memory components of memory system 300 are arranged such that these memory components may form a grid of memory components with multiple rows and columns while still allowing each memory component to be adjacent to any previous or subsequent memory components on a respective edge of the memory components. Such an arrangement of memory components allows for flexibility in layout for memory system 300 that maintains the ability for memory component to memory component signal transmission.

B. Memory Component Embodiments

As noted above, in embodiments, by way of illustrative example and not limitation, a memory system comprises a plurality of memory components (i.e., memory blocks) that communicate data and transaction information from memory component to memory component, and a memory system may comprise two or more (e.g., up to ‘N’) memory components. In embodiments, memory components are located adjacent to each other at respective edges such that no logic or communication/data connections are included therebetween. For example, according the described techniques, ancillary logic (e.g., memory select logic, feedthrough buffering, register stages, etc.) and muxing required by the memory components are included within each memory component. Furthermore, the memory components are configured such that transaction information and data are passed from one memory component to the next, adjacent memory component.

FIG. 4 shows a block diagram of an example memory system 400 including a memory component 402 for implementing the above-referenced improvements. As illustrated, memory system 400 may also include one or more additional memory component prior to or subsequent to memory component 402, such as memory component 404 (prior) and memory component 406 (subsequent) although additional components are contemplated in embodiments but not shown for illustrative clarity. In embodiments, one or more of memory component 402, memory component 404, and memory component 406 are adjacent to any previous or subsequent memory components of memory system 400 on respective edges of these memory components. In embodiments, memory component 402 may be the first or the last memory component of memory system 400. That is, memory component 402 may be configured as any given memory component of a memory system, e.g., memory system 400, according to various embodiments described herein. Memory system 400 of FIG. 4 may be a further embodiment of memory system 200 of FIG. 2 and/or of memory system 300 of FIG. 3, and memory component 402, memory component 404, and/or memory component 406 may be further embodiments of memory components of memory system 200 of FIG. 2 and/or of memory system 300 of FIG. 3. In embodiments, memory component 404 and memory component 406 may be configured similarly or substantially the same as memory component 402.

Memory component 402 includes a storage array 408, first selector control logic 410, and second selector control logic 412. Memory component 402 also includes a first retiming register 418, a second retiming register 422, a third retiming register 424, and a read output register 472. Memory component 402 also includes a first selector 416, a second selector 420, a third selector 426, a fourth selector 428, and a fifth selector 430. Memory component 402 may also include bypass logic 414, in some embodiments. First retiming register 418, second retiming register 422, third retiming register 424, first selector 416, second selector 420, third selector 426, fourth selector 428, fifth selector 430, first selector control logic 410, second selector control logic 412, and/or bypass logic 414 may collectively correspond to instances of local logic components of FIGS. 2-3, according to embodiments.

It should be noted that various connections and connectors described herein may comprise one or more physical connections/connectors, e.g., as a multi-bit bus, or may be serial connections/connectors, as would be understood by one of skill in the relevant art(s) having the benefit of this disclosure. For clarity and ease of illustration, each connection/connector is only shown as a single line.

Memory component 402 is configured to receive a bank identification (ID) via bank ID input connector 464, read data via read data input connector 432, read transaction information via read request input connector 444, and write transaction information via write input connector 448. In embodiments, bank ID input connector 464 may comprise a portion of read request input connector 444 and write input connector 448. Memory component 402 is also configured to provide or output read data via a connector 442, read transaction information via a connector 454, and write transaction information via a connector 456.

Read data is received via read data input connector 432 by first selector 416 that also receives read data that is locally stored in storage array 408 via a connector 434 from read output register 472 through a connector 436, as shown. However, it should be noted that in some embodiments, read output register 472 may not be included in memory component 402. First selector 416 also receives a read data selector configuration input from first selector control logic 410 via a connector 466. First selector 416 provides its output to first retiming register 418 and to second selector 420 via a connector 440. First retiming register 418 provides its output to second selector 420 via a connector 438. Second selector 420 also receives a bypass selector configuration input via a connector 458. Second selector 420 provides its output via connector 442.

Read transaction information is received via read request input connector 444 by third selector 426 and second retiming register 422. Second retiming register 422 provides its output to third selector 426 and to fifth selector 430 via a connector 446. Third selector 426 also receives the bypass selector configuration input via connector 458. Third selector 426 provides its output via connector 454. Write transaction information is received via write input connector 448 by fourth selector 428 and third retiming register 424. Third retiming register 424 provides its output to fourth selector 428 and to fifth selector 430 via a connector 450. Fourth selector 428 also receives the bypass selector configuration input via connector 458. Fourth selector 428 provides its output via connector 456. Fifth selector 430 also receives a read/write transaction selector configuration input from second selector control logic 412 via a connector 468. Fifth selector 430 provides its output to storage array 408 via a connector 452.

One or more paths through memory component 402 for read data, read transaction information, and write transaction information may collectively comprise further embodiments of a portion of memory data and transaction information connector 214 of memory system 200 in FIG. 2 and/or further embodiments of a portion of memory data and transaction information connector 314 of memory system 300 in FIG. 3. For example, write transaction information may traverse memory system 400 in a memory component to memory component fashion (as shown through memory component 402), by either: write input connector 448, fourth selector 428, and connector 456; or write input connector 448, connector 450, fourth selector 428, and connector 456. Read data and read transaction information may traverse memory system 400 in a similar exemplary fashion through memory component 402 as illustrated in FIG. 4 and described above. However, it should be noted that memory component to memory component paths as contemplated herein may include additional or alternative connectors and/or components in embodiments.

In embodiments, the bypass selector configuration input provided via connector 458 may be generated and provided by bypass logic 414. For example, bypass logic 414 may include an AND gate with an inverted input and a non-inverted input (or other equivalent logic). The inverted input may receive a design for test (DFT) bypass input on a connector 460, and the non-inverted input may receive a bypass select input on a connector 462. The output of bypass logic 414 is then provided as the bypass selector configuration input provided via connector 458. In other embodiments, the bypass selector configuration input may be provided via connector 458 from a component external to memory component 402 and bypass logic 414 may not be included in memory component 402. When the bypass select input is set to a first value (e.g., a logical ‘0’), memory component 402 is configured to re-time or pipeline data and information via internal registers, e.g., first retiming register 418, second retiming register 422, and third retiming register 424, before providing the data and information to a subsequent memory component (e.g., memory component 406) or to a receiver external to memory system 400. When the bypass select input is set to a second value (e.g., a logical ‘1’), memory component 402 is configured to bypass the internal registers (i.e., feedthrough) and only buffer data and information (i.e., with no re-timing) using, e.g., logical components such as second selector 420, third selector 426, and/or fourth selector 428, before providing the data and information. The value of the bypass select input may be static or dynamic according to embodiments, and may be based on a system clock frequency or period.

Each of first retiming register 418, second retiming register 422, third retiming register 424, and read output register 472 may be configured to receive a system clock input via a clock connector 470, although in embodiments each memory component of a memory system may have a respective clock input. The system clock and/or memory component clocks may be configured to be enabled/disabled according to first selector control logic 410 and/or second selector control logic 412. Furthermore, first selector control logic 410 and second selector control logic 412 may each receive the bank ID via bank ID input connector 464, write transaction information via write input connector 448, and/or read transaction information via read request input connector 444 as inputs (actual connections not shown for illustrative clarity). Each memory component of a memory system has a unique bank ID that may be static or dynamic according to embodiments.

Storage array 408 may be configured to store memory data, such as data to be written to storage array 408 (write data) and/or data that may be read from storage array 408 (read data). In embodiments, storage array 408 may comprise an array of memory storage elements, such as SRAM storage elements, as would be understood by one of skill in the relevant art(s) having the benefit of this disclosure. Storage array 408 may be of any storage size, such as by way of example and not limitation, 0.5 Mb to 2 Mb, although both larger and smaller storage sizes are contemplated for storage array 408. Storage array 408 may include an array input register 474 in embodiments that may be configured to receive the output of fifth selector 430 via connector 452, and to receive the system clock input via clock connector 470 to “clock in” data and/or information received by storage array 408. As noted herein, the output of fifth selector 430 on connector 452 comprises write transaction information (via connector 450) or read transaction information (via connector 446), and storage array 408 (including any additional respective control logic, not shown) may receive these outputs and, either store write data for a valid write request according to the write transaction information or read data out for a valid read request according to the read transaction information. Write transaction information may include a write request (e.g., a write valid bit(s), a write bank ID bit(s), a write address, etc.) and/or write data, and read transaction information may include a read request (e.g., a read valid bit(s), a read bank ID bit(s), a read address, etc.), as would be understood by one of skill in the relevant art(s) having the benefit of this disclosure. Write transaction information and read transaction information may include a “no operation” (NoOp) field/bit or values associated with a NoOp in existing fields/bits, according to embodiments.

In embodiments, first selector control logic 410 and second selector control logic 412 may be any combination of logical components, circuits, state machines, etc., configured to control the selection of inputs for first selector 416 and fifth selector 430 respectively. In some embodiments, first selector control logic 410 and second selector control logic 412 may collectively comprise a single component with multiple outputs. First selector control logic 410 and second selector control logic 412 may be configured to receive the bank ID via bank ID input connector 464, write transaction information via write input connector 448, and/or read transaction information via read request input connector 444 as inputs (actual connections not shown for illustrative clarity) and generate their respective outputs according to one or more of these inputs, in embodiments.

For instance, first selector control logic 410 may use one or more read valid bits and the read bank ID of the read transaction information, as well as the bank ID received via bank ID input connector 464 to output a value for read data selector configuration input signal on connector 466. For instance, if the read bank ID does not match the bank ID or if the read valid bit(s) do not indicate a valid memory read transaction, the value of the read data selector configuration input signal on connector 466 may be set to a first value that configures first selector 416 to select and output the read data received on read data input connector 432. If the read bank ID matches the bank ID and if the read valid bit(s) indicate(s) a valid memory read transaction, the value of the read data selector configuration input signal on connector 466 may be set to a second value that configures first selector 416 to select and output the read data that is stored in storage array 408 that is received via connector 434. In embodiments, signals, data, and/or information used by first selector control logic 410 to generate its output may be received by first selector control logic 410 in the same clock cycle as the inputs to first selector 416, or one or more system clock cycles ahead of these inputs.

Second selector control logic 412 may use one or more read valid bits and the read bank ID of the read transaction information, one or more write valid bits and the write bank ID of the write transaction information, and/or the bank ID received via bank ID input connector 464 to output a value for the read/write transaction selector configuration input from second selector control logic 412 via connector 468. For instance, if the read bank ID matches the bank ID and if the read valid bit(s) indicate a valid memory read transaction, the value of the read/write transaction selector configuration input signal on connector 468 may be set to a first value that configures fifth selector 430 to select and output the read transaction information received on connector 446. If the write bank ID matches the bank ID and if the write valid bit(s) indicate(s) a valid memory write transaction, the value of the read/write transaction selector configuration input signal on connector 468 may be set to a second value that configures fifth selector 430 to select and output the write transaction information received via connector 450. In embodiments, signals, data, and/or information used by second selector control logic 412 to generate its output may be received by second selector control logic 412 in the same clock cycle as the inputs to second retiming register 422 and/or third retiming register 424, or one or more system clock cycles ahead of these inputs. In embodiments, signals, data, and/or information used by second selector control logic 412 to generate its output may be received by second selector control logic 412 in the same clock cycle as the inputs to fifth selector 430, or one or more system clock cycles ahead of these inputs.

It should be noted that alternative approaches to determining if memory components are the intended recipient of memory transactions, e.g., other than matching bank IDs with memory transaction information, are contemplated herein, and the described examples above are not considered to be limiting.

In embodiments, first selector control logic 410 and second selector control logic 412 may also be configured to provide a NoOp configuration value (not shown) for configuring first selector 416 and fifth selector 430, respectively, if a NoOp indication is present in the read transaction information and the write transaction information.

First retiming register 418, second retiming register 422, third retiming register 424, and/or read output register 472 may be any type of flip-flops or banks/arrays thereof, registers or banks/arrays thereof, and/or any other logic component/circuit configured to hold or register data and operate according to a clock signal (such as latches, etc.). These registers may be of the same type or of different types in embodiments. As described above, each of first retiming register 418, second retiming register 422, third retiming register 424, and read output register 472 receives a respective data input and a system clock input. First retiming register 418, second retiming register 422, and third retiming register 424 are configured to register or “clock” (i.e., pipeline) data on their respective data paths for system timing purposes.

For example, first retiming register 418 is configured to “clock” or register read data received from first selector 416 on connector 440 before such read data is provided (via second selector 420, as shown in FIG. 4) to a subsequent memory component (e.g., memory component 406, as shown in FIG. 4) or to a receiver external to the memory system when memory component 402 is the last memory component of memory system 400. In embodiments where memory component 402 is the last memory component of memory system 400, memory component 402 may be the only memory component of memory system 400 to provide its respective read data output to the external receiver.

Second retiming register 422 is configured to “clock in” or register read transaction information received via read request input connector 444 from either of a previous memory component (e.g., memory component 404, as shown in FIG. 4) or from a source external to memory system 400 when memory component 402 is the first memory component of memory system 400. In embodiments where memory component 402 is the first memory component of memory system 400, memory component 402 may be the only memory component of memory system 400 to receive the read transaction information from the external source. Second retiming register 422 is thus configured to “clock out” such read transaction information before such read transaction information is provided (via third selector 426, as shown in FIG. 4) to a subsequent memory component (e.g., memory component 406, as shown in FIG. 4) or to a receiver external to the memory system when memory component 402 is the last memory component of memory system 400. In embodiments where memory component 402 is the last memory component of memory system 400, memory component 402 may be the only memory component of memory system 400 to provide its respective read transaction information output to the external receiver.

Third retiming register 424 is configured to “clock in” or register write transaction information received via write input connector 448 from either of a previous memory component (e.g., memory component 404, as shown in FIG. 4) or from a source external to memory system 400 when memory component 402 is the first memory component of memory system 400. In embodiments where memory component 402 is the first memory component of memory system 400, memory component 402 may be the only memory component of memory system 400 to receive the write transaction information from the external source. Third retiming register 424 is thus also configured to “clock out” such write transaction information before such write transaction information is provided (via fourth selector 428, as shown in FIG. 4) to a subsequent memory component (e.g., memory component 406, as shown in FIG. 4) or to a receiver external to the memory system when memory component 402 is the last memory component of memory system 400. In embodiments where memory component 402 is the last memory component of memory system 400, memory component 402 may be the only memory component of memory system 400 to provide its respective write transaction information output to the external receiver.

Read output register 472 is configured to register data stored in storage array 408 that is to be output by storage array 408 to first selector 416 in response to a valid read request.

First selector 416, second selector 420, third selector 426, fourth selector 428, and/or fifth selector 430 may be any type of mux or banks/arrays thereof and/or any other logic component/circuit configured to make a selection from inputs according to a configuration input signal. These selectors may be of the same type or of different types in embodiments. As described above, each of first selector 416, second selector 420, third selector 426, fourth selector 428, and/or fifth selector 430 receives respective data inputs and a configuration input.

First selector 416 is configured to select between read data that is locally stored in and read out from storage array 408 via connector 434, and input read data received on read data input connector 432, to be provided as read data output from memory component 402 via connector 442 according to the read data selector configuration input from first selector control logic 410 via connector 466. The read data received on read data input connector 432 may include read data stored in a previous memory component (e.g., memory component 404, as shown in FIG. 4 or another previous memory component not shown) when memory component 402 is not the first memory component of memory system 400 and a valid memory read transaction to a previous memory component has occurred. In embodiments where memory component 402 is the first memory component of memory system 400, or if a memory read transaction for a previous memory component has not occurred, the read data received on read data input connector 432 may be default read data (e.g., all 1's, all 0's, or a combination thereof), may be no data (e.g., a high impedance value ‘z’, a floating or un-driven value ‘x’, etc.), or any other read data value.

In embodiments, first selector 416 may be a 2:1 mux that is configured to function as a local point-to-point mux between memory component 402 and subsequent memory component 406. Each memory component of memory system 400 may include a respective first selector 416 that is configured to function as a point-to-point mux between a given memory component and its subsequent memory component. In this way, according to the embodiments and techniques herein, a memory system, e.g., memory system 400 of FIG. 4, comprises multiple instances of local point-to-point muxes instead of a large L:1 mux or distributed external muxes (e.g., mux 106 as described with respect to FIG. 1) as used in prior solutions, thus achieving improvements in area and routing for the memory system.

Second selector 420, third selector 426, and fourth selector 428 are configured to select between respective registered (pipelined) inputs and respective bypass (feedthrough) inputs according to bypass selector configuration input via connector 458. When registered inputs are selected, the data/information received is said to be “retimed,” and when non-registered inputs are selected, the data/information received is said to be “bypassed.” For example, second selector 420 is configured to receive registered or retimed read data from first retiming register 418 and to receive bypassed (i.e., non-registered) read data from first selector 416. Third selector 426 is configured to receive registered or retimed read transaction information from second retiming register 422 and to receive bypassed (i.e., non-registered) read transaction information via read request input connector 444. Fourth selector 428 is configured to receive registered or retimed write transaction information from third retiming register 424 and to receive bypassed (i.e., non-registered) write transaction information via write input connector 448.

Fifth selector 430 is configured to select between read transaction information on connector 446 and write transaction information on connector 450 to be provided to storage array 408 via connector 452 according to the read/write transaction selector configuration input received from second selector control logic 412 via connector 468. For example, when provided with a first value for the read/write transaction selector configuration input from second selector control logic 412 via connector 468, read transaction information is provided to storage array 408, and when provided with a second value for the read/write transaction selector configuration input from second selector control logic 412 via connector 468, write transaction information is provided to storage array 408. Embodiments are also contemplated where storage array 408 may be other than a single-port storage array as illustrated in FIG. 4 (e.g., a storage array that supports one read transaction and one write transaction per clock cycle), and in such embodiments, connector 446 and connector 450 may be connected to storage array 408, while fifth selector 430 and second selector control logic 412 may not be included.

In embodiments, either of the read data selector configuration input from first selector control logic 410 via connector 466 or the read/write transaction selector configuration input from second selector control logic 412 via connector 468 may indicate a NoOp and respectively configure first selector 416 and fifth selector 430 to provide NoOp output values. A NoOp output may comprise default data (e.g., all 1's, all 0's, or a combination thereof), may be no data (e.g., a high impedance value ‘z’, a floating or un-driven value ‘x’, etc.), or any other data value.

It is also contemplated that embodiments may include multiple instances of read request input connector 444 and/or write input connector 448 (request interfaces), and in such embodiments additional corresponding selector and retiming components, as similarly described above with respect to read request input connector 444 and write input connector 448, may also be included. In embodiments where the number of request interfaces is greater than the number of access requests per clock cycle supported by the storage array (e.g., storage array 408), additional logic (that may be external logic, not shown) may be included to ensure that nor more than the supported number of access requests per clock cycle are directed the memory (e.g., memory system 400).

### IV. Example Operational Embodiments

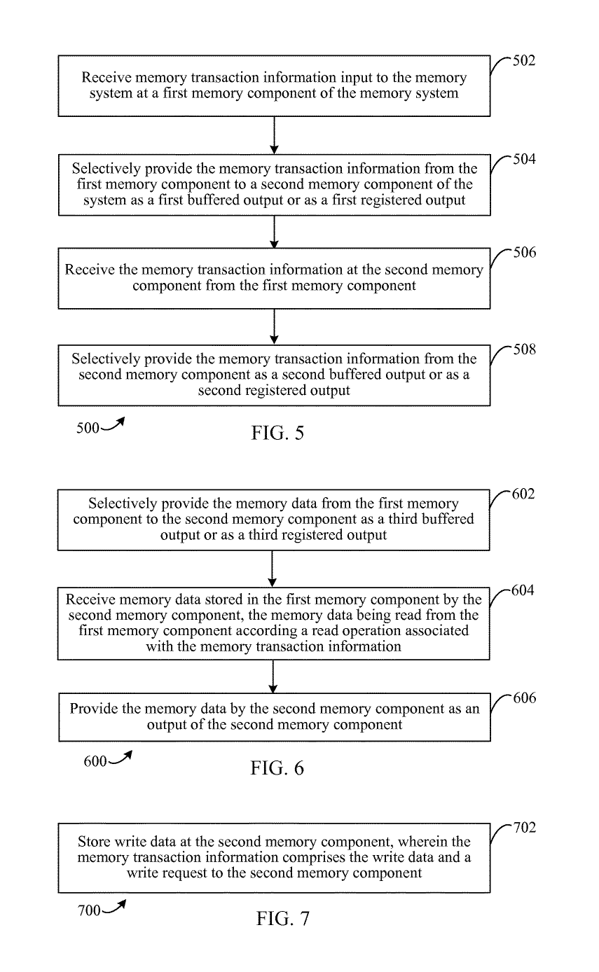

Turning now to FIG. 5, a flowchart 500 is shown. Example embodiments described herein may be configured to perform feedthrough operations and retiming on data and information paths to support memory to memory requests according to flowchart 500. For instance, memory system 200 of FIG. 2, memory system 300 of FIG. 3, memory system 400 and memory component 402 of FIG. 4, along with any respective components/subcomponents thereof, may be configured to perform feedthrough operations and retiming on data and information paths to support memory to memory requests according to flowchart 500. Flowchart 500 is described as follows.

Memory transaction information input to the memory system is received at a first memory component of the memory system (502). For instance, memory transaction information such as read transaction information, read data, and/or write transaction information, as described herein, may be received at memory component 402 of memory system 400 in FIG. 4. Such memory transaction information may be received from a previous memory component (e.g., memory component 404) or from a source external to the memory system in embodiments.

The memory transaction information is selectively provided from the first memory component to a second memory component of the system as a first buffered output or as a first registered output (504). For example, second selector 420 of memory component 402 in FIG. 4 may be used to select between a buffered version of output read data on connector 440 and a registered version of the output read data on connector 438 and provide its output on connector 442. Similarly, third selector 426 of memory component 402 in FIG. 4 may be used to select between a buffered version of read transaction information on read request input connector 444 and a registered version of the read transaction information on connector 446 and provide its output on connector 454. Likewise, fourth selector 428 of memory component 402 in FIG. 4 may be used to select between a buffered version of write transaction information on write input connector 448 and a registered version of the write transaction information on connector 450 and provide its output on connector 456. Each of these described outputs may be provided to a subsequent memory component (e.g., memory component 406 of FIG. 4, and/or as shown in FIGS. 2-3) or as memory system outputs to a receiver external to the memory system (e.g., as shown in FIGS. 2-3 and described with respect thereto). As shown in FIG. 4, each of the selectors described in 504 may be concurrently configured for retiming (registered inputs) or bypass (non-registered inputs) according to the value of bypass selector configuration input on connector 458, although in embodiments per-selector configurations are contemplated herein.

The memory transaction information is received at the second memory component from the first memory component (506). For instance, as shown in FIGS. 2-4, memory components of a memory system may be adjacent to each other and support memory component to memory component paths and transactions. As noted in the description with respect to FIG. 4, memory component 406 is a memory component subsequent to memory component 402 and may be configured similarly or substantially the same as memory component 402. Per 506, the memory transaction information that is selectively provided from the first memory component to the second memory component of the system as a first buffered output or as a first registered output (described above in 504) may be received from memory component 402 by memory component 406 having a corresponding configuration as memory component 402. In embodiments, memory component 402 and memory component 406 may be adjacently placed (e.g., super-adjacent placement) such that there are no physical connections or logic between the memory components—thus, a memory component to memory component transaction path is realized according to the techniques described herein.

The memory transaction information is selectively provided from the second memory component as a second buffered output or as a second registered output (508). In embodiments, memory component 406 may selectively provide the memory transaction information in a similar or identical manner as described above for memory component 402 in 504. The memory transaction information provided by memory component 406 may be provided to a further subsequent memory component of memory system 400, or to a receiver external to the memory system in embodiments where memory component 406 is the last memory component of memory system 400. In embodiments where memory component 406 is the last memory component, memory component 406 may be the only memory component of memory system 400 to provide memory transaction information to the external receiver.

In some example embodiments, one or more of operations 502, 504, 506, and/or 508 of flowchart 500 may not be performed. Moreover, operations in addition to or in lieu of operations 502, 504, 506, and/or 508 may be performed. Further, in some example embodiments, one or more of operations 502, 504, 506, and/or 508 may be performed out of order, in an alternate sequence, or partially (or completely) concurrently with each other or with other operations.

Turning now to FIG. 6, a flowchart 600 is shown. Example embodiments described herein may be configured to perform feedthrough operations and retiming on data and information paths to support memory to memory requests according to flowchart 600. For instance, memory system 200 of FIG. 2, memory system 300 of FIG. 3, memory system 400 and memory component 402 of FIG. 4, along with any respective components/subcomponents thereof, may be configured to perform feedthrough operations and retiming on data and information paths to support memory to memory requests according to flowchart 600. Flowchart 600 may be a further embodiment of flowchart 500 of FIG. 5, and one or more operations described in flowchart 600 may be performed in addition to, or alternatively to, those described in flowchart 500, according to embodiments. Flowchart 600 is described as follows.

Memory data from the first memory component is selectively provided to the second memory component as a second buffered output or as a second registered output (602). For instance, memory data may comprise read data, i.e., data that is requested to be read from a memory component of memory system 400 of FIG. 4 according to a memory read transaction, as described herein. In embodiments, memory component 402 of memory system 400 in FIG. 4 may selectively provide read data via second selector 420 by selecting between a buffered version of output read data on connector 440 and a registered version of the output read data on connector 438, and to provide its output on connector 442. As shown in FIG. 4, second selector 420 may be configured for retiming (registered inputs) or bypass (non-registered inputs) according to the value of bypass selector configuration input on connector 458.

The memory data stored in the first memory component is received by the second memory component, the memory data being read from the first memory component according a read operation associated with the memory transaction information (604). For example, as shown in FIGS. 2-4, memory components of a memory system may be adjacent to each other and support memory component to memory component paths and transactions. As noted in the description with respect to FIG. 4, memory component 406 is a memory component subsequent to memory component 402 and may be configured similarly or substantially the same as memory component 402. The memory data that is selectively provided from the first memory component to the second memory component of the system as a second buffered output or as a second registered output described above (602) may be received from memory component 402 by memory component 406 having a corresponding configuration as memory component 402. In embodiments, memory component 402 and memory component 406 may be adjacently placed (e.g., super-adjacent placement) such that there are no physical connections or logic between the memory components—thus, a memory component to memory component transaction path is realized according to the techniques described herein. According to 604, the memory data is read data that was stored in memory component 402, e.g., in storage array 408 as shown in FIG. 4. In such embodiments, a valid read transaction targeting storage array 408 of memory component 402 may cause storage array 408 to read out read data associated with a read address corresponding to provided read transaction information. That is, read data from storage array 408 of memory component 402 is read out and provided to the subsequent memory component (e.g., memory component 406), and thus a memory component to memory component transaction path is realized according to the techniques described herein.

The memory data is provided by the second memory component as an output of the second memory component (606). For instance, memory component 406 may provide the memory data (e.g., the received read data) in a similar or identical manner as described herein for memory component 402. The read data provided by memory component 406 may be read data that was stored in storage array 408 of memory component 402, or that was stored in a memory component before memory component 402. The memory data provided by memory component 406 may be provided to a further subsequent memory component of memory system 400, or to a receiver external to the memory system in embodiments where memory component 406 is the last memory component of memory system 400. In embodiments where memory component 406 is the last memory component, memory component 406 may be the only memory component of memory system 400 to provide memory data to the external receiver.

In some example embodiments, one or more of operations 602, 604, and/or 606 of flowchart 600 may not be performed. Moreover, operations in addition to or in lieu of operations 602, 604, and/or 606 may be performed. Further, in some example embodiments, one or more of operations 602, 604, and/or 606 may be performed out of order, in an alternate sequence, or partially (or completely) concurrently with each other or with other operations.

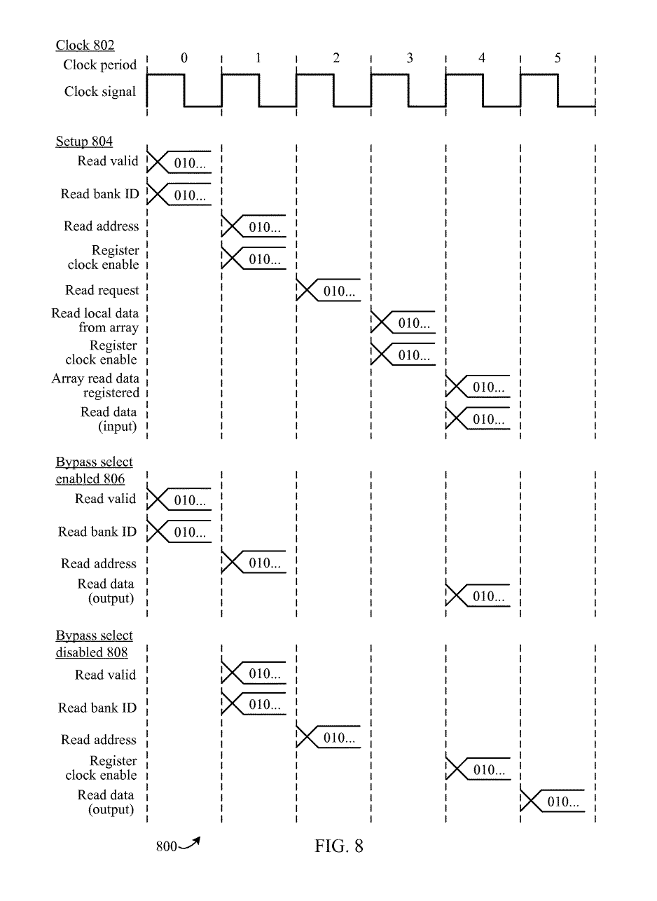

Turning now to FIG. 7, a flowchart 700 is shown. Example embodiments described herein may be configured to perform feedthrough operations and retiming on data and information paths to support memory to memory requests according to flowchart 700. For instance, memory system 200 of FIG. 2, memory system 300 of FIG. 3, memory system 400 and memory component 402 of FIG. 4, along with any respective components/subcomponents thereof, may be configured to perform feedthrough operations and retiming on data and information paths to support memory to memory requests according to flowchart 700. Flowchart 700 may be a further embodiment of flowchart 500 of FIG. 5, and the operation described in flowchart 700 may be performed in addition to, or alternatively to, those described in flowchart 500, according to embodiments. Flowchart 700 is described as follows.

Write data is stored at the second memory component, where memory transaction information comprises write data and a write request to the second memory component (702). For example, memory transaction information, as described herein, may comprise write data and write transaction information received by memory component 402 of FIG. 4 via write input connector 448. In embodiments, subsequent to 506 of flowchart 500 in FIG. 5, write data may be stored in a corresponding storage array of memory component 406. That is, memory component 402 of memory system 400 may selectively provide to memory component 406 write transaction information including a write request and write data for a write operation targeting memory component 406.

In some example embodiments, operation 702 of flowchart 700 may not be performed. Moreover, operations in addition to or in lieu of operation 702 may be performed. Further, in some example embodiments, operation 702 may be performed partially (or completely) concurrently with other operations described herein.

As noted above, the techniques and embodiments described herein provide for memories with feedthrough and retiming paths to support memory to memory requests. In FIG. 8, a timing diagram 800 is shown. Timing diagram 800 may be representative of one or more example embodiments described, such as a memory read transaction in accordance with feedthrough operations and retiming on data and information paths to support memory to memory requests. For instance, memory system 200 of FIG. 2, memory system 300 of FIG. 3, memory system 400 and memory component 402 of FIG. 4, along with any respective components/subcomponents thereof, may have example timing for memory read operations according to timing diagram 800. Timing diagram 800 is described by way of example and not limitation, and with respect to memory system 400 of FIG. 4 for purposes of illustration as follows.

Timing diagram 800 includes four sections: a clock section 802, a setup section 804, a bypass select enabled section 806, and a bypass select disabled section 808. Information and data in these sections of timing diagram 800 are conceptually represented as binary data “010 . . . ” for illustrative purposes only, and these conceptual representations are not intended to be limiting or to represent actual data or information. Additionally, signals in timing diagram 800 are illustrated with respect to the arrival of the signals, but it should be understood that the signals may remain valid for one or more clock periods after arrival. Furthermore, some signals may be omitted in certain embodiments, such as the register clock enable signals described below (for embodiments in which retiming registers are not disabled). Still further, the timing shown in timing diagram 800 is not to be considered limiting, but rather is an illustrative example that demonstrates the techniques and embodiments described herein. That is, embodiments described herein may be configured such that the signals shown in timing diagram 800, such as but not limited to, read transaction information signals and write transaction information signals, may arrive during other clock periods than as shown.

Clock section 802 shows a clock signal and clock periods 0-5 for reference with the remaining sections of timing diagram 800. The clock signal may be a system clock signal input, e.g., via a clock connector 470, or a per memory component clock signal as described herein. The clock signal may have any operating frequency and corresponding period or cycle according to design implementations for memory systems as described herein.

Setup section 804 corresponds to the receipt of signals for a memory transaction by a memory component of a memory system, such as memory component 402 of memory system 400 in FIG. 4. For instance, during the receipt of signals for memory data and memory transaction information by memory component 402, a read valid signal and a read bank ID signal (i.e., read transaction information) are received during the initial clock period ‘0’, for example via read request input connector 444. In embodiments, first selector control logic 410 and second selector control logic 412 may receive the read valid signal and read bank ID signal, as described above with respect to FIG. 4.

In clock period ‘1’, a read address signal (i.e., read transaction information) is received, for example via read request input connector 444, and a register clock enable signal may be provided to a register that receives read transaction information (e.g., second retiming register 422 of memory component 402). This allows second retiming register 422 an initial setup time before the read transaction information is registered and clocked out to storage array 408. It should be noted that according to this description, second retiming register 422 is configured as an input register for storage array 408 in addition to being a retiming register. The read address signal may also be received by first selector control logic 410 and second selector control logic 412 as described herein, according to embodiments.

In clock period ‘2’, storage array 408 may receive the read transaction information (i.e., a read request) from second retiming register 422 via connector 446, fifth selector 430, and connector 452 shown in FIG. 4. That is, based on at least a portion of the read transaction information, second selector control logic 412 may select and output the read transaction information input on connector 446 via connector 452 to storage array 408.

In clock period ‘3’, storage array 408 may read local data stored therein that is associated with the read address of the read transaction information, and then provide the stored data (local read data) to read output register 472. A register clock enable signal may also be provided to read output register 472 in clock period ‘3’. This allows read output register 472 an initial setup time before the local read data is registered and clocked out.

In clock period ‘4’, the local read data is registered and clocked out by read output register 472, and is provided to first selector 416 via connector 434. Additionally, first selector 416 receives memory data (i.e., read data) that is provided to memory component 402 via read data input connector 432.

Accordingly, the signals described in setup section 804 are received and setup for being provided to a subsequent memory component (e.g., memory component 406) or to a receiver that is external to memory system 400 (e.g., receiver 218 of FIG. 2).

Bypass select enabled section 806 corresponds to timing for outputs of a memory transaction by a memory component of a memory system (such as a read transaction for memory component 402 of memory system 400 in FIG. 4) in which retiming registers are bypassed (i.e., feedthrough). For instance, the illustrated example timing in bypass select enabled section 806 corresponds to a value of the bypass selector configuration input on connector 458 that enables second selector 420 and third selector 426 to select non-registered versions of their respective inputs on connector 440 and read request input connector 444. As shown, the read valid signal and the read bank ID signal are each available for output by memory component 402 on connector 454 in the same clock period (‘0’) in which they were received, as shown in setup section 804. That is, because second retiming register 422 is bypassed, there are no registers in the path that comprises read request input connector 444 and connector 454 via third selector 426 (which is not a register). Likewise, the read address signal is also available for output by memory component 402 on connector 454 in the same clock period (‘1’) in which it was received, for similar reasons. Similarly, the read data that is selected for output by first selector 416 is available to be output by memory component 402 on connector 442 in the same clock period (‘4’) in which the input read data was received via read data input connector 432. In other words, in the case where input read data is received from a previous memory component of a memory system or an external source and is to be the read data output, and in the case where the storage array of the memory component is the target of a memory read transaction and stored, local data of the memory component is to be output, the read data to be output is available therefor in the same clock period in which the input read data was received via read data input connector 432.

Accordingly, when configured for feedthrough and retiming registers are bypassed, the read data that is output by memory component 402 is available after four clock periods from the initial receipt of the first portion of the read transaction information (i.e., a four pipeline stage read transaction).

Bypass select disabled section 808 corresponds to timing for outputs of a memory transaction by a memory component of a memory system (such as memory component 402 of memory system 400 in FIG. 4) in which retiming registers are utilized, not bypassed. For instance, the illustrated example timing in bypass select disabled section 808 corresponds to a value of the bypass selector configuration input on connector 458 that enables second selector 420 and third selector 426 to select registered versions of their respective inputs on connector 438 and connector 446. As shown, the read valid signal and the read bank ID signal are each available for output by memory component 402 on connector 454 in the next clock period (‘1’) after they were received (‘0’). That is, because second retiming register 422 is utilized and not bypassed, there is a retiming register in the path that comprises read request input connector 444, connector 446, and connector 454 via third selector 426. Likewise, the read address signal is also available for output by memory component 402 on connector 454 in the next clock period (‘2’) after which it was received (‘1’), for similar reasons. Similarly, the read data that is selected for output by first selector 416 is available to be output by memory component 402 on connector 442 in the next clock period (‘5’) after which the input read data was received (‘4’) via read data input connector 432 (subsequent to the register clock enable shown in clock period ‘4’) because the read data is registered by first retiming register 418. In other words, in the case where input read data is received from a previous memory component of a memory system or an external source and is to be the read data output, and in the case where the storage array of the memory component is the target of a memory read transaction and stored, local data of the memory component is to be output, the read data to be output is available therefor in the clock period after the input read data was received via read data input connector 432 because the read data to be output has been retimed/pipelined by first retiming register 418.

Accordingly, when configured for retiming/pipelining and retiming registers are utilized and not bypassed, the read data that is output by memory component 402 is available after five clock periods from the initial receipt of the first portion of the read transaction information (i.e., a five pipeline stage read transaction).

As noted above, the selection of memory components, such as memory component 402, as being either a bypass memory component (as in bypass select enabled section 806) or a pipeline/registered memory component (as in bypass select disabled section 808) may be dependent on the operating clock period (i.e., cycle time) of the memory system. For example, according to embodiments, signals such as memory data and memory transaction information described herein may be required to traverse a path between two registers in an amount of time that is less than the clock cycle time. This allows such signals to “clocked out” and “clocked in” by registers within the clock cycle time to meet timing constraints, as would become apparent to one of skill in the relevant art(s) having the benefit of this disclosure. Given a clock cycle time, these signals may be able to traverse one or more (‘P’) feedthrough memory components before being registered in a retiming memory component as described herein.

In the disclosed embodiments by way of example, several timing paths may be considered in determining the ratio (‘P:1’) of feedthrough memory components per pipeline memory component. These timing paths may include, but are not limited to, a feedthrough path, a registered feedthrough path, a storage array output register path, and an input access register path.

The feedthrough path is active when the bypass function of a memory component is active, and therefore read transaction information signals and write transaction information signals are not registered outputs (but are buffered outputs). The feedthrough path comprises logical component delay from input to output of a memory component (e.g., the path comprising read request input connector 444 and connector 454 via third selector 426).

The registered feedthrough path is active when the bypass function of a memory component is inactive, and therefore signals for locally stored read data being read from the memory component, read transaction information signals, and write transaction information signals are registered outputs. The registered feedthrough path comprises register to output access time (e.g., from first retiming register 418, from second retiming register 422, or from third retiming register 424, or in some embodiments, the longest timing path of these three).

The storage array output register path is active when the bypass function of a memory component is active, and therefore signals for locally stored read data being read from the memory component are not registered subsequent to being clocked out from a storage array as outputs. The storage array output register path comprises output access time from the storage array output register (e.g., read output register 472 of FIG. 4) to output from the memory component.

The input access register path comprises input setup time for read transaction information signals and write transaction information signals that are registered as inputs (e.g., respectively by second retiming register 422 and third retiming register 424 of FIG. 4).

Consider an illustrative example memory system having a ratio ‘P:1’, where ‘P’ equals 2, and a given clock cycle time. Such an example memory system requires that the sum of time for the storage array output register path, the feedthrough path, and the input access register path be less than or equal to the clock cycle time; and that the sum of time for the registered feedthrough path, two times the feedthrough path, and the input access register path be less than or equal to the clock cycle time. However, as clock cycle times may vary by memory system, higher or lower ratios ‘P:1’, where P is greater than zero, may be configured according to following equations:

Path 3+((P−2)×Path 1)+Path 4≦clock cycle time, (Equation 1)

and

Path 2+((P−1)×Path 1)+Path 4≦clock cycle time, (Equation 2)

where Path 1 is the feedthrough path, Path 2 is the registered feedthrough path, Path 3 is the storage array output register path, and Path 4 is the input access register path

It should be noted that a ratio ‘P:1’ where ‘P’ equals 0 is also contemplated herein. In such embodiments, each memory component of a memory system would be a retiming/pipeline memory component. For example, with respect to memory system 400 of FIG. 4, the bypass selector configuration input on connector 458 of memory component 402, as well corresponding bypass selector configuration inputs for memory component 404, memory component 406, and any other memory components of memory system 400, would be set to a value such that each selector of the memory components of memory system 400 selected their respective registered input versions from retiming registers.

### V. Further Example Embodiments and Advantages

As noted above, systems and devices, including memory systems and components, may be configured in various ways with feedthrough and retiming paths to support memory to memory requests according to the techniques and embodiments provided. For instance, in embodiments, memory components of a memory system may provide memory data and memory transaction information from memory component to memory component.

Additionally, memory components of a memory system may be adjacently placed with no physical connectors, muxing, and/or ancillary logic therebetween. Such configurations allow for memory system circuit advantages of up to approximately 16-18% or more improvements in the density of memory systems, or alternatively, the inclusion of up to approximately 16-18% or more additional memory components in a given memory system area.

From a system level perspective, the described techniques and embodiments allow for additional memory depth not previously available in existing solutions. Products in which memory systems configured according to the described techniques and embodiments are utilized may realize cost savings due to reduced die area and improved physical design and integration considerations, such as but not limited to, routing, placement, less resource intensive memory system timing closure, etc. Additionally, product performance improvements due to additional memory available may also be realized.

The described techniques and embodiments may be utilized in any large memory systems, and the advantages described herein become even more beneficial as semiconductor devices continue to use increasingly larger and larger memory systems. The described techniques and embodiments provide value and performance benefits to products and industries that drive for increasing amounts of memory capacity. However, any chip architecture using fairly large memories and/or multi-read memories can benefit from the density and memory capacity advantages provided herein.

The further example embodiments and advantages described in this Section may be applicable to embodiments disclosed in any other Section of this disclosure.

Embodiments and techniques, including methods, described herein may be performed in various ways such as, but not limited to, being implemented by hardware, software, firmware, and/or any combination thereof. For example, embodiments may be implemented as memory systems, such as SRAM systems, specifically customized hardware, ASICs, electrical circuitry, and/or the like.

### VI. Example Computer Implementations

Memory system 200 of FIG. 2, memory system 300 of FIG. 3, memory system 400 and memory component 402 of FIG. 4, along with any respective components/subcomponents thereof, and/or any flowcharts, further systems, sub-systems, and/or components disclosed herein may be implemented in hardware (e.g., hardware logic/electrical circuitry), or any combination of hardware with software (computer program code or instructions configured to be executed in one or more processors or processing devices) and/or firmware. In embodiments with respect to the example computer implementations in this Section, main memory, memory cards and memory sticks, memory devices, and/or the like may include and or implement the described techniques and embodiments.

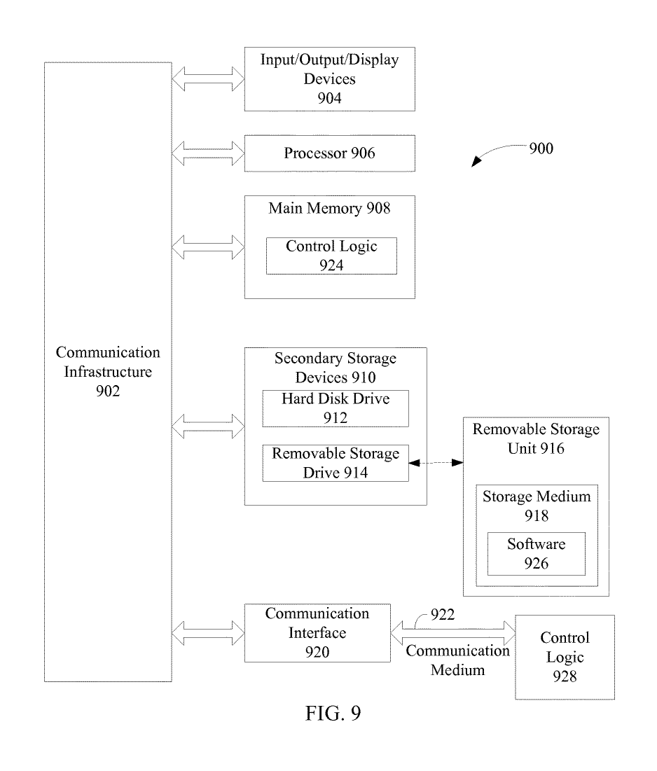

The embodiments described herein, including circuitry, devices, systems, methods/processes, and/or apparatuses, may be implemented in or using well known processing devices, communication systems, servers, and/or, computers, such as a processing device 900 shown in FIG. 9. It should be noted that processing device 900 may represent communication devices/systems, entertainment systems/devices, processing devices, and/or traditional computers in one or more embodiments. For example, analog-to-digital conversion circuits for spread spectrum noise reduction, and any of the sub-systems and/or components respectively contained therein and/or associated therewith, may be implemented in or using one or more processing devices 900 and similar computing devices.

Processing device 900 can be any commercially available and well known communication device, processing device, and/or computer capable of performing the functions described herein, such as devices/computers available from International Business Machines®, Apple®, Sun®, HP®, Dell®, Cray®, Samsung®, Nokia®, etc. Processing device 900 may be any type of computer, including a desktop computer, a server, etc., and may be a computing device or system within another device or system.

Processing device 900 includes one or more processors (also called central processing units, or CPUs), such as a processor 906. Processor 906 is connected to a communication infrastructure 902, such as a communication bus. In some embodiments, processor 906 can simultaneously operate multiple computing threads, and in some embodiments, processor 906 may comprise one or more processors.

Processing device 900 also includes a primary or main memory 908, such as random access memory (RAM). Main memory 908 has stored therein control logic 924 (computer software), and data.

Processing device 900 also includes one or more secondary storage devices 910. Secondary storage devices 910 include, for example, a hard disk drive 912 and/or a removable storage device or drive 914, as well as other types of storage devices, such as memory cards and memory sticks. For instance, processing device 900 may include an industry standard interface, such a universal serial bus (USB) interface for interfacing with devices such as a memory stick. Removable storage drive 914 represents a floppy disk drive, a magnetic tape drive, a compact disk drive, an optical storage device, tape backup, etc.

Removable storage drive 914 interacts with a removable storage unit 916. Removable storage unit 916 includes a computer useable or readable storage medium 918 having stored therein computer software 926 (control logic) and/or data. Removable storage unit 916 represents a floppy disk, magnetic tape, compact disk, DVD, optical storage disk, or any other computer data storage device. Removable storage drive 914 reads from and/or writes to removable storage unit 916 in a well-known manner.

Processing device 900 also includes input/output/display devices 904, such as touchscreens, LED and LCD displays, monitors, keyboards, pointing devices, etc.

Processing device 900 further includes a communication or network interface 920. Communication interface 920 enables processing device 900 to communicate with remote devices. For example, communication interface 920 allows processing device 900 to communicate over communication networks or mediums 922 (representing a form of a computer useable or readable medium), such as LANs, WANs, the Internet, etc. Network interface 920 may interface with remote sites or networks via wired or wireless connections.

Control logic 928 may be transmitted to and from processing device 900 via the communication medium 922.

Any apparatus or manufacture comprising a computer useable or readable medium having control logic (software) stored therein is referred to herein as a computer program product or program storage device. This includes, but is not limited to, processing device 900, main memory 908, secondary storage devices 910, and removable storage unit 916. Such computer program products, having control logic stored therein that, when executed by one or more data processing devices, cause such data processing devices to operate as described herein, represent embodiments.

Techniques, including methods, and embodiments described herein may be implemented by hardware (digital and/or analog) or a combination of hardware with one or both of software and/or firmware. Techniques described herein may be implemented by one or more components. Embodiments may comprise computer program products comprising logic (e.g., in the form of program code or software as well as firmware) stored on any computer useable medium, which may be integrated in or separate from other components. Such program code, when executed by one or more processor circuits, causes a device to operate as described herein. Devices in which embodiments may be implemented may include storage, such as storage drives, memory devices, and further types of physical hardware computer-readable storage media. Examples of such computer-readable storage media include, a hard disk, a removable magnetic disk, a removable optical disk, flash memory cards, digital video disks, random access memories (RAMs), read only memories (ROM), and other types of physical hardware storage media. In greater detail, examples of such computer-readable storage media include, but are not limited to, a hard disk associated with a hard disk drive, a removable magnetic disk, a removable optical disk (e.g., CDROMs, DVDs, etc.), zip disks, tapes, magnetic storage devices, MEMS (micro-electromechanical systems) storage, nanotechnology-based storage devices, flash memory cards, digital video discs, RAM devices, ROM devices, and further types of physical hardware storage media. Such computer-readable storage media may, for example, store computer program logic, e.g., program modules, comprising computer executable instructions that, when executed by one or more processor circuits, provide and/or maintain one or more aspects of functionality described herein with reference to the figures, as well as any and all components, capabilities, and functions therein and/or further embodiments described herein.

Such computer-readable storage media are distinguished from and non-overlapping with communication media (do not include communication media). Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wireless media such as acoustic, RF, infrared and other wireless media, as well as wired media and signals transmitted over wired media. Embodiments are also directed to such communication media.

The techniques and embodiments described herein may be implemented as, or in, various types of devices. For instance, embodiments may be included, without limitation, in processing devices (e.g., illustrated in FIG. 9) such as computers and servers, as well as communication systems such as switches, routers, gateways, and/or the like, communication devices such as smart phones, home electronics, gaming consoles, entertainment devices/systems, etc. A device, as defined herein, is a machine or manufacture as defined by 35 U.S.C. §101. That is, as used herein, the term “device” refers to a machine or other tangible, manufactured object and excludes software and signals. Devices may include digital circuits, analog circuits, or a combination thereof. Devices may include one or more processor circuits (e.g., central processing units (CPUs), processor 906 of FIG. 9), microprocessors, digital signal processors (DSPs), and further types of physical hardware processor circuits) and/or may be implemented with any semiconductor technology in a semiconductor material, including one or more of a Bipolar Junction Transistor (BJT), a heterojunction bipolar transistor (HBT), a metal oxide field effect transistor (MOSFET) device, a metal semiconductor field effect transistor (MESFET) or other transconductor or transistor technology device. Such devices may use the same or alternative configurations other than the configuration illustrated in embodiments presented herein.

### VII. Conclusion

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described exemplary embodiments, but should be defined only in accordance with the following claims and their equivalents.

1. A memory system that comprises:
a first memory component that includes within, a first selection component and a first retiming register; and
a second memory component that includes within, a second selection component;
the first memory component being configured to:
receive memory transaction information that is input to the memory system, and read data, and
provide to the second memory component the memory transaction information and, based on the first selection component, selectively provide first read data stored in the first memory component as a first buffered output, or as a first registered output from the first retiming register; and
the second memory component being configured to:
receive the memory transaction information and the first read data from the first memory component, and
provide the memory transaction information, and provide the first read data or second read data stored in the second memory component as an output of the second memory component based on the second selection component.

2. The memory system of claim 1, wherein the memory system comprises a series of memory components and wherein the first memory component is configured to receive the memory transaction information and the read data from a previous memory component in the series of memory components, the read data being previous read data stored in the previous memory component.

3. The memory system of claim 1, wherein the memory system comprises a series of memory components and wherein the second memory component is configured to provide the output to a subsequent memory component in the series of memory components.

4. The memory system of claim 1, wherein the first memory component is configured to receive the memory transaction information from a source external to the memory system, and is the only memory component of the memory system to receive the memory transaction information from the source.

5. The memory system of claim 1, wherein the second memory component is configured to provide at least a portion of the output to a receiver external to the memory system, and is the only memory component of the memory system to provide a respective output to the receiver.

6. The memory system of claim 1, wherein the first memory component and the second memory component are SRAM components.

7. The memory system of claim 1, wherein the first memory component and the second memory component are adjacent to each other at a respective component edge with no physical, external connections therebetween.

8. The memory system of claim 1, wherein the second memory component includes within, a second retiming register;
the second memory component configured to:
provide the first read data or the second read data as a second buffered output, or as a second registered output from the second retiming register.

9. The memory system of claim 8, wherein the second memory component includes within, a third selection component;
the third selection component configured to determine whether the first read data or the second read data is provided as the second buffered output or as the second registered output.

10. A memory system that comprises:
a first memory component that includes within, a first retiming register; and
a second memory component that includes within, a second retiming register;
the first memory component configured to:
receive memory transaction information input to the memory system, wherein the memory transaction information comprises one or more of write request information, write data or read request information, and
selectively provide to the second memory component the memory transaction information as a first buffered output, or as a first registered output from the first retiming register; and
the second memory component configured to:
receive the memory transaction information from the first memory component, and
selectively provide the memory transaction information as a second buffered output, or as a second registered output from the second retiming register.

11. The memory system of claim 10, wherein the first memory component includes within, a first selection component, and wherein the second memory component includes within, a second selection component;
the first selection component configured to determine whether the memory transaction information is provided as the first buffered output or as the first registered output; and
the second selection component configured to determine whether the memory transaction information is provided as the second buffered output or as the second registered output.

12. The memory system of claim 10, wherein the first registered output and the second registered output are respectively selected based at least on a clock frequency of the memory system.

13. The memory system of claim 10, wherein at least one of the first retiming register or the second retiming register is further configured as an input register for at least a portion of the memory transaction information to the first memory component and the second memory component, respectively.

14. The memory system of claim 10, wherein the read request information comprises at least one of:
bank identification information; or
a read address.

15. The memory system of claim 10, wherein the first memory component is configured to receive the memory transaction information:
from a previous memory component in a series of memory components that comprise the memory system; or
from a source external to the memory system, wherein the first memory component is the only memory component of the memory system to receive the memory transaction information from the source.

16. The memory system of claim 10, wherein the second memory component is configured to provide the output:
to a subsequent memory component in a series of memory components that comprise the memory system; or
to a receiver external to the memory system, wherein the second memory component is the only memory component of the memory system to provide a respective output to the receiver.

17. A method performed in a memory system, the method comprising:
receiving memory transaction information input to the memory system at a first memory component of the memory system;
selectively providing the memory transaction information from the first memory component to a second memory component of the system as a first buffered output or as a first registered output;
receiving the memory transaction information at the second memory component from the first memory component; and
selectively providing the memory transaction information from the second memory component as a second buffered output or as a second registered output.

18. The method of claim 17, further comprising:
receiving memory data stored in the first memory component by the second memory component, the memory data being read from the first memory component according a read operation associated with the memory transaction information; and
providing the memory data by the second memory component as an output of the second memory component.

19. The method of claim 18, further comprising:
selectively providing the memory data from the first memory component to the second memory component as a third buffered output or as a third registered output.

20. The method of claim 17, wherein the memory transaction information comprises write data and a write request to the second memory component;
the method further comprising storing the write data at the second memory component.
